(19) United States
(12) Patent Application Publication
(10) Pub. No.: US 2015/0002104 A1
(43) Pub. Date: Jan. 1, 2015

(54) Method and device for adjusting a load current as a function of an internal resistance

(71) Applicant: Bender GmbH & Co. KG, Gruenberg (DE)

(72) Inventor: Winfried Moell, Laubach (DE)

(21) Appl. No.: 14/315,750

(22) Filed: Jun. 26, 2014

(30) Foreign Application Priority Data
Jul. 1, 2013 (DE) 10 2013 212 821.5

(51) Int. Cl. H02H 9/02; H02H 9/04; B60L 11/18; H02H 3/20; H02J 7/02; G01R 21/133; H02H 3/08

(52) U.S. Cl. CPC H02H 9/02; G01R 21/133; H02H 9/04; H02H 3/08; H02H 3/20; H02J 7/022; B60L 11/1811; B60L 11/1818
USPC 320/162; 361/93.7

(57) ABSTRACT

The invention relates to a method and a device for adjusting a load current during operation of a load which is connected to a supply line of a power supply system via load connections. An internal resistance of the power supply system effective on the load connections is determined and used for adjusting the load current. The basic idea of the present invention is based on the determination and monitoring of the internal resistance of the supplying power grid so as to early recognize potential risks and to initiate appropriate measures. From the determined internal resistance value, a statement can be made with regard to the quality of the power supply system, such as a building installation, from the main power distribution to the supply line in the supplying cable outlet to the load connections.

This application incorporates by reference the disclosure of German Patent Application 10 2013 212 821.5.

### TECHNICAL FIELD

The invention relates to a method and a device for adjusting a load current during operation of a load which is connected to a supply line of a power supply system via load connections.

### BACKGROUND

Starting from a circuit arrangement in which an electric consumer is connected as a load to a supply line of a power supply system, it must be ensured with regard to electrical safety that the load current via the load connections to the consumer and thus also the current in the supply line do not exceed a maximum value. The fire risk may increase during the operation with high load currents if the power loss cannot be dissipated because of an increased electrical resistance, especially in older or insufficiently secured distribution systems of the power supply system or at load connections with high contact or transition resistances. Oftentimes, a maximum capacity of the power supply line is nominally known with regard to current strength, but the momentary technical condition of the installation is disregarded so that there is the risk of an overload.

For further explanation of the object at hand, a charging process of an electric vehicle is considered in the following as an example for a load operation. The on-board electrical system of the electric vehicle with the electric energy storage unit corresponds to the load and the charging current flowing into the electric vehicle represents the load current.

Since the electric energy storage units of an electric vehicle are regularly charged, the risks are to be considered here as well which arise during the charging process. In particular if the electric vehicle is connected to a commercial power socket for charging, it must be made sure that the power supply grid behind the socket is actually configured for high load currents (charging currents). In fact, the charging current which flows through the charging connections of a Schuko or CEE plug socket can have up to 32 A in case of uncontrolled charging (charging mode 2).

Some charging devices offer an adjusting option for the charging current. The user can select a reduced maximum charging current to adjust the latter to the circumstances of the local electric installation.

In particular, it is currently not ensured in the course of the progressing development in electro-mobility that for charging, an electric vehicle is always connected to an electric installation that meets all regulations. Thus, the safe and reliable charging of electric vehicles as well as the operation of a conventional load is directly linked to the electric state of the building installation. This applies even more to cases where unsuitable extension cables are used for connecting the consumer to commercial power sockets.

It proves disadvantageous in the afore-mentioned arrangements that the momentary electric state of the supplying grid is not taken into consideration during load operation, in particular in terms of the quality of its supply lines.

### SUMMARY

Therefore, it is the object of the present invention to propose a method and a device which increase the electrical safety during the operation of a load on a supply line of a power supply system.

With regard to a method, the object is attained in connection with the preamble of claim 1 in that an internal resistance of the power supply system effective at the load connections is determined and used for adjusting the load current.

The basic idea of the present invention is advantageously based on the determination and monitoring of the internal resistance of the supplying power grid in order to early recognize potential risks and to initiate appropriate measures.

In this context, the electrical resistance of the power supply system effective at the load connections from outside of the power supply system is called internal resistance, hereinafter designated R.

From the determined internal resistance value Rᵢ, a statement can be made regarding the quality of the power supply system, such as a building installation, from the main power distribution to the supply line in the supplying cable outlet to the lead connections.

In a preferred embodiment, the internal resistance Rᵢ is constantly monitored for an exceedance of a predefinable internal resistance limit during the load operation.

During the load operation, the internal resistance Rᵢ is continuously monitored as to whether a specific internal resistance limit valid for the power supply system is exceeded. If a deterioration of this kind is registered, it can be answered automatically or by human intervention. Thus, it is possible to recognize critical supply circuits early and to prevent potential fire damage.

Furthermore, at least one terminal voltage (Vₖ) applied at the load connections between an outer conductor and a neutral conductor and the associated load current Iₗ flowing through the load connections are measured to determine the internal resistance Rᵢ.

The internal resistance Rᵢ of the power supply system effective between an outer conductor and the neutral conductor with respect to the load connections is determined by a current/voltage measurement on a specific terminal pair, such as L1 and N. For this purpose, the terminal voltage (Vₖ) applied at the load connections is tapped and the load current Iₗ flowing through these contacts is measured. Besides using it for determining the internal resistance Rᵢ, the progression of the measured terminal voltage Vₖ can also be used to recognize a power overload due to an excess load current Iₗ because of a damaged consumer, for example. In case of a multi-phase power supply grid, at least one internal resistance Rᵢ is determined, for instance between the outer conductor L1 and the neutral conductor N; but alternatively or additionally, the internal resistances Rᵢ can be determined, as well, with regard to the respective other outer conductors, such as L2 and L3, and the neutral conductor N, and be monitored and used for assessing the quality of the power supply grid.

In another advantageous embodiment, the internal resistance Rᵢ is determined through a load current change (ΔIₗ) while simultaneously determining a voltage difference (ΔV), which results from the measured terminal voltage (Vₖ).

For determining the internal resistance Rᵢ, the load current Iₗ is changed by a value ΔIₗ and the resulting voltage difference ΔV at the load connections is used by measuring the terminal voltage Vₖ to calculate the internal resistance Rᵢ. If the current/voltage is measured starting from an open circuit voltage V₀ assumed to be constant, Rᵢ=ΔV/ΔIₗ applies for the internal resistance, wherein ΔV=V₀−Vₖ, further assuming the validity of a linear current/voltage relation (Ohm's law). The voltage difference ΔV, however, can also be determined in any given load case without knowing the open circuit voltage V₀.

Advantageously, the load current change ΔIₗ for determining the internal resistance Rᵢ occurs through a pulsed change of the load current ΔIₗ by a predefinable value.

With the aid of this pulsed load current change ΔIₗ, which corresponds to a short-term load current change ΔIₗ in the form of a measuring pulse, the internal resistance Rᵢ is determined while simultaneously determining the voltage difference ΔV resulting from said current change ΔIₗ. In case of an increase of the load current, the latter cannot rise further than up to a maximum load current Iₗₘₐₓ. A pulsed load current change ΔIₗ is to be understood to mean a quick change of short duration with respect to typically occurring grid voltage fluctuations that are of a slower nature and are corrected automatically. The load current change ΔIₗ and the corresponding determination of the voltage difference ΔV for determining the internal resistance Rᵢ thus are not influenced by the typical grid voltage fluctuations occurring in the operation of a power supply system.

Furthermore, the determination of the internal resistance Rᵢ is triggered manually or in a time-controlled manner. The determination of the internal resistance Rᵢ can be manually triggered by the system operator at the beginning of a load operation to be newly started, for example, in particular after the new installation of a consumer prior to its first activation. In addition, a time-controlled manner of determining the internal resistance Rᵢ during the load operation is possible so as to be able to recognize creeping changes in the quality of the power supply system over a longer period of time. A repeated determination in adjustable time intervals is suitable for this purpose.

Advantageously, the determination of the internal resistance Rᵢ during load operation is triggered by an operation-related change of the load current Iₗ. Supplementary to a manual or time-controlled determination of the internal resistance Rᵢ, the determination can also be triggered as a function of the temporal progression of the load current Iₗ. If the load current changes under different operating or usage conditions of the consumer, such as the current drain of an electric welding device, this current change can be used to trigger a current/voltage measurement for determining the internal resistance Rᵢ.

Preferably, a maximum load current Iₗₘₐₓ can be preset. Thus, it is possible to take into account the quality of the supplying power grid in advance by adjusting a system-specific maximum load current Iₗₘₐₓ. In this manner, the load current Iₗ can either be limited to a maximum load current Iₗₘₐₓ for safety reasons or the load can be operated with a current strength that is maximally permissible for the given power supply system if there is certainty that the installation works reliably.

For adjusting the system-specific maximum load current Iₗₘₐₓ, the latter can be derived from a maximum permissible power dissipation Pᵥₘₐₓ in the power supply system. For this purpose, the user does not directly select a maximum current value, but follows the power dissipation caused by the internal resistance Rᵢ of the power supply system, from which a loss-dependent maximum load current Iₗₘₐₓ can be calculated. There is a fire risk starting at a power dissipation of 60 W in the load circuit of the power supply system, for example. Hence, the maximum load current Iₗₘₐₓ can be derived from a maximum permissible power dissipation Pᵥₘₐₓ of 30 W, for example, according to Iₗₘₐₓ=Pᵥₘₐₓ/ΔV, wherein ΔV is the voltage drop over the internal resistance Rᵢ of the power supply system.

Advantageously, the load operation is shut down if the internal resistance limit is exceeded.

To preclude a risk to personnel and systems due to a potential fire, the load operation is interrupted by means of a shutdown device when the internal resistance Rᵢ exceeds a possibly system-specific internal resistance limit. In case of an electric energy storage unit of an electric vehicle being charged, the charging process would thus be at least temporarily terminated.

Alternatively to the shutdown of the load operation, the load current Iₗ can be reduced if the internal resistance limit is exceeded.

If the consumer is appropriately configured, it may continue to operate with lower current consumption and, where applicable, with limited functionality. In particular, it can thus be made sure in case of an electric vehicle being charged that a risk of overload of the power supply system is almost entirely precluded when the quality of the power supply system deteriorates during the charging operation, but that the charging of the energy storage unit is not interrupted.

In another embodiment, a load circuit in the power supply system supplying the load is shut down if the internal resistance limit is exceeded, this combined with an electric protection device in the power supply system.

In connection with a protection device arranged within the power supply system, at least the part of the power supply system carrying the load current Iₗ can be shut down when an exceedance of the internal resistance limit is detected. In this way, electrical safety is further increased.

When an overcurrent protection device in the load current circuit supplying the load in the power supply system is triggered, the associated load current Iₗ is preferably recorded and used as a load current limit.

If the overcurrent protection device in the power supply system is triggered because of an excess load current Iₗ flowing through the load connections, the load current Iₗ present in the moment of the triggering can be recorded and be used as a load current limit in a subsequent load operation. The maximum load current Iₗₘₐₓ can be alternatively derived from this load current limit, including a safety margin. Thus, a repeated triggering of the overcurrent protection device in the power supply system due to an excess load current Iₗ is avoided when the load operation is resumed.

In another embodiment, at least a threshold value is calculated for the internal resistance Rᵢ, upon exceedance of which a warning is triggered.

The warning notifies the user of a deteriorating or imminent critical condition of the supplying power grid and may prompt an inspection of the system before an incident occurs.

In a preferred embodiment, an electric energy storage unit is charged by means of a charging current as load current Iₗ.

The method according to the invention is particularly suitable for monitoring a charging process of an electric energy storage unit because the charging current strength is usually not tied to a specific constant current value. The charging process thus can be understood as a load operation, wherein the charging current corresponds to the load current Iₗ. By adjusting the load current Iₗ with the aid of the calculated internal resistance Rᵢ, the energy storage unit can be charged with a preferably maximum load current Iₗ that is adapted for the supplying grid.

Advantageously, the electric energy storage unit of an electric vehicle provided with a charging device is charged in the charging process, wherein the electric vehicle is connected to the supply line of the power supply system by a charging cable via the load connections.

In addition to the charging of stationary energy storage units, the method according to the invention can be used for charging the electric energy storage units of electric vehicles. In this context, the electric vehicle is connected to the supply line of the power supply system by the charging cable via a plug device, which comprises the load connections.

With regard to a device, the object underlying the invention is attained in connection with the preamble of claim 17 by a current measuring device and a voltage measuring device for determining an internal resistance Rᵢ of the power supply system effective at the load connections.

In implementation of the method according to the invention, the device according to the invention comprises a current measuring device and a voltage measuring device. From the current and voltage values registered at the load connections, the internal resistance Rᵢ of the power supply system effective at these “terminals” can be determined. The current measuring device can be embodied as a differential current measuring device.

In another advantageous embodiment, the device comprises a comparing device for monitoring the internal resistance Rᵢ for an exceedance of a predefinable internal resistance limit.

According to the basic idea of the present invention, the calculated internal resistance Rᵢ is monitored for an exceedance by being compared to an internal resistance limit so as to obtain a statement regarding the momentary condition and thus the quality of the installation of the power supply system.

Furthermore, the device comprises an adjusting device for changing the load current Iₗ to determine the internal resistance Rᵢ and for reducing the load current Iₗ in case of an exceedance of the internal resistance limit.

The internal resistance Rᵢ is calculated according to the relation Rᵢ=ΔV/ΔIₗ from the change of the load current ΔIₗ and the consequently occurring voltage change ΔV. To be able to perform the current change ΔIₗ for this calculation and, if necessary, a reduction of the load current Iₗ when the internal resistance limit is exceeded, the device comprises the adjusting device. It is also possible to reduce the load current Iₗ to a value of zero, which corresponds to an interruption of the load operation.

For shutting down the load operation, the device further comprises a shutdown device. If the internal resistance limit is exceeded, the load operation can be shut down by means of the shutdown device alternatively or additionally to an initial reduction of the load current Iₗ.

In another advantageous embodiment, the device comprises a calculating unit for combining the measured and preset values and a control unit for controlling the sequence of the measuring and calculating tasks.

On the basis of the measured current and voltage values as well as of the preset and stored values, the calculating unit performs the calculations for determining the internal resistance Rᵢ. The control unit can be embodied as a microcontroller and defines the temporal sequence of the method steps. For instance, the control unit dictates when and by reason of which events a new determination of the internal resistance Rᵢ is to be performed.

### BRIEF DESCRIPTION OF THE DRAWINGS

Further advantageous embodiment features arise from the following description and from the drawings, which illustrate preferred embodiments of the invention with the aid of examples. In the figures:

FIG. 1: shows a schematic illustration of a power supply grid with a device according to the invention for adjusting a load current,

FIG. 2: shows an implementation of the method for charging an energy storage unit of an electric vehicle.

### DETAILED DESCRIPTION

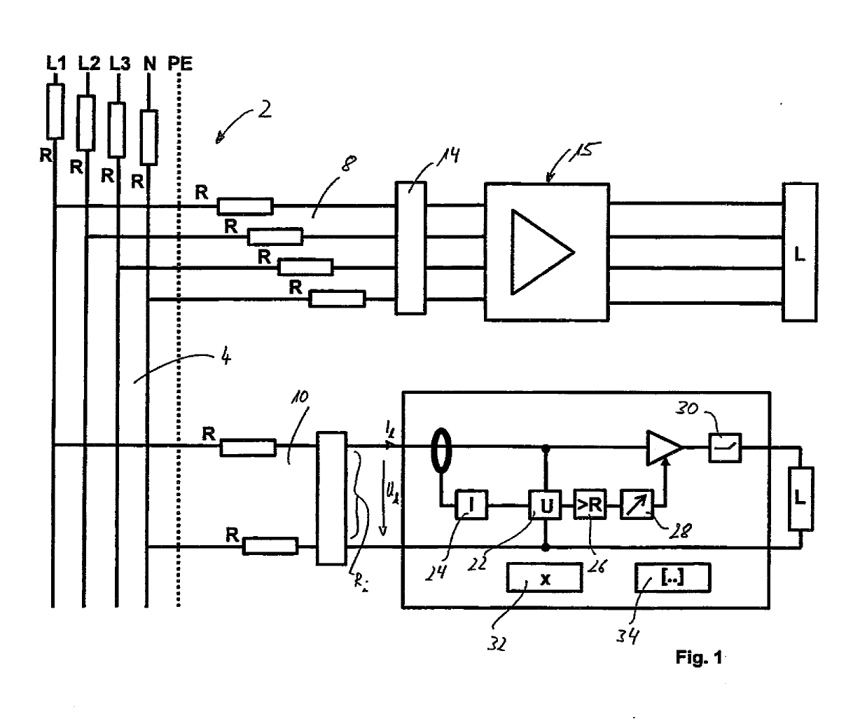

FIG. 1 shows a power supply system 2, which is embodied as an earthed 3-phase supply grid including the active conductors L1, L2, L3 and N as well as the protective earth conductor PE. The power supply system 2 is composed of the main system 4 and a 3-phase supply line 8 branching off the main system 4 and another single-phase supply line 10 branching off the main system 4. A load L is connected as a consumer to each of the to supply lines 8, 10 via load connections 14. A device 15 according to the invention is connected between the load connections 14 and the load L in each of the supply lines 8, 10. The line and transition resistances of the power supply system 2 are illustrated as concentrated loss resistances R.

The functionality of the method according to the invention and the device 15 according to the invention implementing said method will be explained in more detail for the single-phase supply line 10. The device 15 for adjusting a load current Iₗ comprises a voltage measuring device 22 and a current measuring device 24. The voltage measuring device 22 measures the terminal voltage Vₖ occurring at the load connections 14 between the conductor L1 and the neutral conductor N, and the current measuring device 24 measures the load current Iₗ which flows through the conductors L1 and N of the supply line 10 and through the load L. By means of the current/voltage measurement, the internal resistance Rᵢ of the power supply system 2 is determined, said internal resistance being “viewed” from the load connections 14 and substantially resulting from the loss resistances R, thus permitting a statement regarding the electric state of the power supply system 2.

As further functional blocks, the device 15 according to the invention comprises a comparing device 26 for monitoring the internal resistance Rᵢ for an exceedance of a predefinable internal resistance limit, an adjusting device 28 for changing and reducing the load current Iₗ, a shutdown device 30 for interrupting the load operation, a calculating unit 32 for associating the measured and preset values, and a control unit 34 for controlling the sequence of the measuring and calculating tasks.

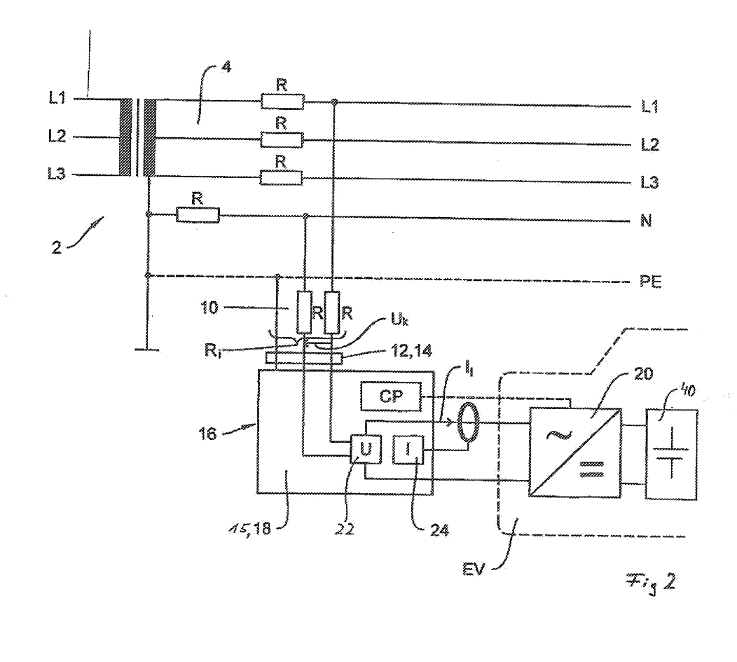

FIG. 2 shows an implementation of the method according to the invention for charging an energy storage unit 40 of an electric vehicle EV by means of an on-board charging device 20. The electric vehicle EV is connected to the conductors L1, N and PE of the supply line 10 via a plug device 12 including load connections (charging connections) 14 and via a charging cable 16.

To meet the normative safety requirements, a mobile protection device 18 (IC-CPD—in-cable control and protective device) with a pilot function (CP—control pilot) for communication with the charging device 20 located within the electric vehicle EV is provided in the charging cable 16 for the case in which the electric energy storage unit 40 of the electric vehicle EV is charged on a commercial power socket (charging mode 2).

The protection device 18 known from the state of the art has been extended by the function according to the invention of internal resistance-dependent adjustment of the load current Iₗ so that the protection device 18 modified in this manner comprises the range of functions of the device 15 according to the invention and thus permits determining an internal resistance Rᵢ of the power supply system 2 effective at the load connections 14 and adjusting the load current Iₗ. In the illustrated embodiment example, only the functions of the voltage measurement 22 and of the current measurement 24 are shown. The modified protection device 18 additionally comprises the non-illustrated functional blocks comparing device (26), adjusting device (28), shutdown device (30), calculating unit (32) and control unit (34).

Alternatively to a full implementation of the method according to the invention into the protection device 18, the device 15 according to the invention may also be integrated into the charging cable 16 as a separate functional unit, as illustrated in FIG. 1, or be connected upstream thereto as a separate structural component or be arranged distributed over several structural components including the protection device 18.

As in the embodiment example with a general load L in FIG. 1, the voltage measuring device 22 measures the occurring terminal voltage Vₖ at the load connections 14, which here function as charging connections, said terminal voltage also being applied to the charging device 20 of the electric vehicle EV as a supply voltage. The current measuring device 24 measures the load current Iₗ which flows through the supply line 10 and which is supplied as charging current to the charging device 20 of the electric vehicle EV. By determining and monitoring the internal resistance Rᵢ of the power supply system 2 effective at the load connections 14 in the manner according to the invention, this current/voltage measurement allows a statement regarding the electric state of the power supply system 2 and permits adapting the charging current (load current Iₗ) to the quality of the supply grid.

A control signal for adjusting the load current Iₗ can be transmitted to the charging device 20 located in the electric vehicle EV by means of the pilot function CP.

A warning can be reported directly at the protection device 18 via and optical and/or acoustic indication or can be transmitted via a CP signal to the on-board charging device 20 and be displayed within the electric vehicle EV.

1. A method for adjusting a load current (Iₗ) during the operation of a load (L) which is connected to a supply line (10) of a power supply system (2) via load connections (14),
characterized in that
an internal resistance (Rᵢ) of the power supply system (2) which is effective on the load connections (14) is determined and used for adjusting the load current (Iₗ).

2. The method according to claim 1,
characterized in that
the internal resistance (Rᵢ) is constantly monitored for an exceedance of a predefinable internal resistance limit during the load operation.

3. The method according to claim 1,
characterized in that
for determining the internal resistance (Rᵢ), at least one terminal voltage (Vₖ) applied at the load connections (14) between an outer conductor (L1, L2, L3) and a neutral conductor (N) and the associated load current (Iₗ) flowing through the load connections (14) are measured.

4. The method according to claim 3,
characterized in that
the internal resistance (Rᵢ) is determined through a load current change (ΔIₗ) while at the same time a voltage difference (ΔV) is determined which results from the measured terminal voltage (Vₖ).

5. The method according to claim 4,
characterized in that
the load current change (ΔIₗ) for determining the internal resistance (Rᵢ) occurs by way of a pulsed change of the load current (Iₗ) by a predefinable value.

6. The method according to claim 1,
characterized in that
the determination of the internal resistance (Rᵢ) is triggered manually or in a time-controlled manner.

7. The method according to claim 1,
characterized in that
the determination of the internal resistance (Rᵢ) is triggered during the load operation by an operation-related change of the load current (Iₗ).

8. The method according to claim 1,
characterized in that
a maximum load current (Iₗₘₐₓ) can be preset.

9. The method according to claim 8,
characterized in that
the maximum load current (Iₗₘₐₓ) is derived from a maximum permissible power dissipation (Pᵥₘₐₓ) in the power supply system (2).

10. The method according to claim 2,
characterized in that
the load operation is shut down if the internal resistance limit is exceeded.

11. The method according to claim 2,
characterized in that
the load current (Iₗ) is reduced if the internal resistance limit is exceeded.

12. The method according to claim 2,
characterized in that
in combination with an electric protection device in the power supply system (2), a load circuit supplying the load (L) in the power supply system (2) is shut down if the internal resistance limit is exceeded.

13. The method according to claim 1,
characterized in that
in case an overcurrent protection device in the load circuit of the power supply system (2) supplying the load (L) is triggered, the associated load current (Iₗ) is recorded and used as a load current limit.

14. The method according to claim 1,
characterized in that
at least one threshold value is calculated for the internal resistance (Rᵢ) whose exceedance triggers a warning.

15. The method according to claim 1,
characterized in that
a charging process of an electric energy storage unit (40) is performed by means of a charging current as load current (Iₗ).

16. The method according to claim 15,
characterized in that
in the charging process, the electric energy storage unit (40) of an electric vehicle (EV) provided with a charging device (20) is charged, the electric vehicle being connected to the supply line (10) of the power supply system (2) by a charging cable (16) via the load connections (14).

17. A device for adjusting a load current (Iₗ) during the operation of a load (L) which is connected to a supply line (10) of a power supply system (2) via load connections (14),
characterized by
a current measuring device (24) and a voltage measuring device (22) for determining an internal resistance (Rᵢ) of the power supply system (2) effective on the load connections (14).

18. The device according to claim 17,
characterized by
a comparing device (26) for monitoring the internal resistance (Rᵢ) for an exceedance of a predefinable internal resistance limit.

19. The device according to claim 17,
characterized by
an adjusting device (28) for changing the load current (Iₗ) to determine the internal resistance (Rᵢ) and for reducing the load current (Iₗ) if the internal resistance limit is exceeded.

20. The device according to claim 17,
characterized by
a shutdown device (30) for shutting down the load operation if the internal resistance limit is exceeded.

21. The device according to claim 17,
characterized by
a calculating unit (32) for combining the measured and predefined values.

22. The device according to claim 17,
characterized by
a control unit (34) for controlling the sequence of the measuring and calculating tasks.
